(19) United States
(12) Patent Application Publication
(10) Pub. No.: US 2008/0281691 A1
(43) Pub. Date: Nov. 13, 2008

(54) REBATE OFFERS FOR RECYCLING ELECTRONIC DEVICES

(76) Inventors: Mark Pearson, Edina, MN (US); Kelley Gregory, Shakopee, MN (US); Thomas Muhs, Chanhassen, MN (US)

Correspondence Address: DORSEY & WHITNEY LLP;INTELLECTUAL PROPERTY DEPARTMENT, SUITE 1500, 50 SOUTH SIXTH STREET, MINNEAPOLIS, MN, 55402-1498, US

(21) Appl. No.: 11/746,874

(22) Filed: May 10, 2007

(51) Int. Cl. G06Q 30/00; H04Q 7/20; H05K 7/00

(52) U.S. Cl. 705/14; 361/679; 455/422.1

(57) ABSTRACT

The present invention is a method of providing a consumer with a rebate in exchange for the recycling of an electronic device. The method comprises receiving a rebate claim and an electronic device from a consumer, providing the consumer with a different and/or new electronic device with a service associated with the different and/or new electronic device, and transferring the monetary value of the rebate to the consumer. In some embodiments, the method comprises accessing client information associated with current cellular phone service clients and selecting target clients for providing rebate offers to based on the client information.

### FIELD OF THE INVENTION

The present invention relates to a method for providing consumers with an incentive to recycle cellular phones and other electronic and mobile electronic devices, and more specifically to a method for providing a consumer with a rebate offer in exchange for returning a cellular phone for recycling. Examples of such other electronic and mobile electronic devices include, but are not limited to, mobile email devices, pagers, two-way radios, and other mobile communication devices, palm computers, pocket computers, radios, televisions, game systems, portable game systems, laptop computers, etc.

### BACKGROUND OF THE INVENTION

Cellular phones and other electronic and mobile electronic devices have become increasingly cost effective means for communication. As a result, such devices have been made available to, and widely used, by an increasing number of people throughout the world. Such devices, however, break down, become technologically surpassed, or the consumer tires of them. A remarkably small number of cellular phones are recycled while millions of these devices tend to be thrown out and end up in landfills. Unfortunately, cellular phones and other electronic and mobile electronic devices contain myriad toxins, such as arsenic, cadmium, and mercury, that can potentially pollute the air and groundwater when burned in incinerators or disposed of in landfills.

Although cellular phone manufacturers have taken an initiative in response to such unfortunate side effects of mass communication, many state legislatures have considered bills that would mandate cellular phone recycling. California, in fact, is the first state to enact cellular phone recycling legislation. The California Cell Phone Recycling Act of 2004 mandates that retailers of new wireless phones implement systems to collect used mobile devices for recycling.

The requirements of the considered bills vary from state to state, but typically the bills require that cellular phone retailers take back used cellular phones from customers for recycling. The retailers must take back the cellular phones free of charge to the customer. Furthermore, the retailers must accept the used cellular phones regardless of the brand of the cellular phone or the original place of purchase.

Additionally, commercial businesses are constantly looking for new ways to retain and/or increase client base. Product marketing rebates are well-known to most consumers and have been used by manufacturers as a tool for promoting and selling products by providing customers with an incentive to purchase particular products, sometimes during a specific period. Typically, in a rebate system, a consumer will purchase a product and subsequently turn in a rebate claim for that product along with identifying information, such as the consumer's name, address, telephone number, e-mail address, etc. On receipt of the rebate claim and consumer identifying information, the manufacturer, or an agent of the manufacturer, such as a rebate processing center, will transfer the value of the rebate to the consumer. Thus, the consumer is provided with an incentive to purchase products having rebate offers.

As such, there is a need in the art that is environmentally and economically beneficial for providing consumers with an incentive to recycle cellular phones and other electronic and mobile electronic devices.

### BRIEF SUMMARY OF THE INVENTION

The present invention, in one embodiment disclosed and claimed herein, is a method of providing a consumer with a rebate in exchange for the recycling of an electronic device. An electronic device and an accompanying rebate claim are received from the consumer. The consumer is subsequently provided with a different or new electronic device, an accompanying service for that device, and the monetary value of the rebate.

One method of the present invention may particularly be directed to mobile electronic devices, and more particularly to cellular phones. The consumer provides a used cellular phone for recycling and submits a rebate claim therewith. In return, the consumer is provided with a new cellular phone and an accompanying cellular phone service contract. The service contract may either be an extension of an existing service contract or a new service contract.

The present invention, in a further embodiment disclosed and claimed herein, is a method of providing an incentive to recycle cellular phones targeted at consumers having existing cellular phone service contracts. A database having client identifying information and cellular phone information associated with a cellular phone owned by each of the client's identified is used to select targeted clients based on particular characteristics of their cellular phone. Once selected, the targeted clients are provided with a rebate offer. The targeted clients may then exchange their used cellular phones and the rebate claim for a new cellular phone, cellular phone service contract, and the monetary value of the rebate.

The present invention, in a further embodiment disclosed and claimed herein, is a method of providing a consumer rebate. A database containing a plurality of clients is used to select target clients. Once selected, the target clients are provided with a rebate offer. An electronic device and an accompanying rebate claim are received from the target client. The target client is provided with a different or new electronic device and an accompanying service for that device.

While multiple embodiments of the present invention are disclosed, still other embodiments of the present invention will become apparent to those skilled in the art from the following detailed description, which shows and describes illustrative embodiments of the invention. As will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

While the specification concludes with claims particularly pointing out and distinctly claiming the subject matter that is regarded as forming the present invention, it is believed that the invention will be better understood from the following description taken in conjunction with the accompanying Figures, in which:

FIG. 1 is a flowchart of a rebate method in accordance with one embodiment of the present invention.

FIG. 2 is a flowchart of a rebate method in accordance with another embodiment of the present invention.

FIG. 3 is a flowchart of a recycling method in accordance with one embodiment of the present invention.

### DETAILED DESCRIPTION

Various embodiments of present invention are a novel and advantageous systems and methods for providing rebates to consumers. Generally, embodiments of the present invention relate to methods for providing consumers with an incentive to recycle used electronic devices, including providing a consumer with a rebate in exchange for returning a used electronic device for recycling. Examples of electronic devices include, but are not limited to, cellular phones, mobile email devices, pagers, two-way radios, and other mobile communication devices, palm computers, pocket computers, radios, televisions, game systems, portable game systems, laptop computers, etc. Embodiments of the present invention may provide a rebate offer to a consumer in relation to the purchase of a new electronic device and/or an accompanying service for an electronic device. The rebate may be provided in addition to, or in conjunction with another existing rebate, such as an existing rebate provided for the purchase of a new electronic device or service contract associated with an electronic device. At some point either prior to submission of the used electronic device, after submission of the used electronic device, or at the time of submission of the used electronic device, a consumer may submit a request to a rebate processing center for redemption of the rebate. A consumer may submit a rebate claim by several methods, generally including, but not limited to, mail, electronically, or telephonically. Similarly, a consumer may submit a rebate claim in accordance with either a traditional paper-based rebate embodiment or a “paperless” rebate embodiment. The rebate processing center may, among other rebate processing, validate the request from the consumer. The rebate processing center may select from a variety of rebate processing and validation systems and methods. Typically, the consumer may then receive compensation for the rebate.

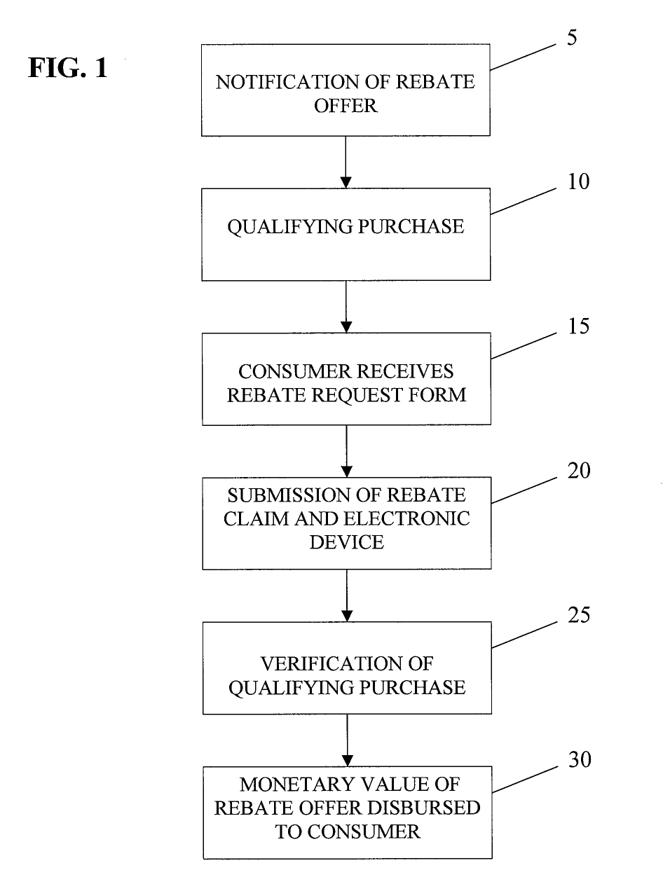

FIG. 1 illustrates a method of providing a consumer with a rebate in exchange for the recycling of an electronic device that may involve a rebate processing center communicating with any or all of manufacturers, distribution centers, retail stores, and consumers. In some embodiments, the rebate processing center, a manufacturer, and distributor may comprise the same entity, comprise entirely separate entities, or comprise of any combination thereof. As used herein, “recycling” refers to the submission of an electronic device for the purpose of any or all of refurbishing, harvesting used parts, reselling, disposing, or the like in accordance with existing environmental policies. In general, a consumer may be notified of a rebate offer wherein in exchange for the purchase of a new electronic device and/or accompanying service for that electronic device and the immediate or subsequent submission of a used electronic device to the rebate processing center, or agents thereof, the consumer receives the monetary value of the rebate offer.

Referring again to FIG. 1, the first step 5 in the method of one embodiment of the present invention may comprise the consumer being notified with regard to the rebate offer. Typically, a notification may comprise a written or oral communication indicating the terms of the rebate offer and instructing consumers with regard to satisfaction of the rebate offer.

Notification may occur in any number of ways. For example, consumers may be notified by a mass distributed flyer or advertisement. Such notifications may appear within printed or electronic media such as newspapers, magazines, journals and the like, or any other advertising medium. Additionally, the notifications may be in the form of an email or delivered mail. Another possibility for notification comprises an advertisement affixed to, or printed on, a package which consumers may subsequently use to send used electronic devices to the rebate processing center. Other forms of notification, such as oral communication or radio and television advertisements, are contemplated to be within the scope of the embodiments of the present invention. In some embodiments, consumers may not learn of the rebate offer until after entering the retail store or distribution center or until after a rebate qualifying purchase has been made.

After notification of the rebate offer, in some embodiments, the consumer may travel to a retail store or distribution center to make a qualifying purchase 10. As used herein, a “qualifying purchase” refers to the purchase of a new electronic device and/or accompanying service contract. The service contract may be either an extension of an existing service contract or a new service contract.

In another embodiment, consumers may be able to make a qualifying purchase 10 in an electronic format, such as through designated sites connected to a global computer information network and accessible to the consumers through the global computer information network. A global computer information network, such as the “internet,” may contain any number of websites which a user may access. Such sites may provide information for purchasing products and user interfaces where users may transmit information about themselves, a product order, a credit card number, and the like. The designated sites, as described in this invention, may typically be administered by retail stores dealing in electronic devices, distribution centers dealing in electronic devices, or providers of accompanying service contracts.

In yet other embodiments, the consumers may be able to initiate the process for returning used electronic devices using a computer information network, such as the internet, prior to making a qualifying purchase or submitting the used electronic device. For example, a consumer may use the internet to fill out a rebate request form, described in detail below, prior to making a qualifying purchase and/or submitting a used electronic device.

Upon completion of a qualifying purchase 10, in some embodiments, the transaction may be recorded by a point-of-sale data processing and storage system. Often, the recording for each qualified purchase may include a transaction identifier or unique identification number (“UIN”). In one embodiment, the UIN may also be recorded on a receipt issued to the consumer. The receipt may be issued to the consumer directly, in the case of an in-store purchase, or electronically transferred to the consumer, in the case of an electronic purchase. The electronic receipt may be in the form of a transfer across a computer network, such as the internet. The point-of-sale data processing and storage system may be any system now known or later developed for recording and processing purchases at the point of sale.

In another embodiment, after making a qualifying purchase 10, consumers may be provided with a primary receipt and a secondary receipt, wherein the primary receipt consists essentially of information associated with all purchases, including items without rebate offers, and further wherein the secondary receipt comprises a record of information associated with the qualifying purchase, including the UIN. The secondary receipt may also contain information with regard to how consumers may effect satisfaction of the rebate offer. In another embodiment, the information contained on the primary receipt and secondary receipt, as described above, may comprise a single receipt.

In some embodiments, the rebate processing center may receive reports from the point-of-sale data processing and storage systems comprising a plurality of purchase data records, e.g., information relating to the sales transactions for the retailer. In one embodiment, purchase data records may typically comprise a list of electronic devices purchased, a list of accompanying service contracts, dates of purchase, UINs, and/or any other information relating to the purchase of an electronic device or accompanying service contract. The purchase data record may include a list of all the products purchased during the transaction and not merely the products associated with a rebate offer. Alternatively, to minimize the purchase data report file size, the purchase data records may be limited to include only the purchased items associated with a rebate offer. The purchase data record may also comprise other data such as the store number, the purchase price of each product purchased, etc. In one embodiment, the report may comprise only those purchase data records having information relating to sales transactions including items associated with rebate offers. In a further embodiment, the rebate processing center may receive the reports electronically, in the form of a transfer across the internet or a tangible electronic storage device containing the electronic file. In other embodiments, the report may be delivered via mail or courier service. Additionally, the rebate processing center may receive the reports of purchase data items on a periodic basis, such as daily, weekly, or other suitable periodic basis. In other embodiments, the rebate processing center may receive the reports at non-regular intervals, such as dates specified by the retailer or rebate processing center.

In some embodiments, after making a qualifying purchase, consumers may also receive a rebate request form 15. Again, the rebate request form may be issued to the consumer directly, in the case of an in-store purchase, or electronically, in the case of an electronic purchase. In other embodiments, the rebate request form may be concomitant with the notification of the rebate offer. In still further embodiments, the rebate request form and the notification may be the same. For example, a portion of the flyer or advertisement may constitute the rebate request form, or the rebate request form may be affixed to, printed on, or contained within packages provided to consumers for submitting used electronic devices.

The rebate request form generally may request transaction information, including the UIN, and selected portions of consumer information. Additionally, the rebate request form may often include a destination address, rebate promotion information, and instructions for submitting material verifying the qualifying purchase. Consumer information may comprise any information that identifies or is associated with a particular consumer, such as the consumer's name, address, phone number, email address, etc. Consumer information may also comprise information regarding a particular consumer's more private information, lifestyle preferences, and/or opinions, such as annual income, places where the consumer typically shops, items the consumer typically purchases, etc. Such information, if requested, may be useful in conducting consumer surveys and typically may be voluntarily offered by the consumer and not required to receive the rebate. Alternatively, in some embodiments, the rebate request form may request only enough information to identify the consumer so that the rebate can be provided to the consumer in a later step of the present method. Upon submission, the rebate request form may constitute a rebate claim.

In some embodiments, before being issued to the consumer, all or a portion of the information requested on the rebate request form may be provided, for example, by the retailer offering the rebate. In one embodiment, such may be the case where a purchase of an electronic device was made at a retail store or over the internet, and the retailer subsequently provides the consumer with the rebate request form. In such cases, much of the consumer information may already be provided, or pre-filled in, on the rebate claim form by the retailer as such consumer information may have already been provided to the retailer for purposes of effectuating the sale of an electronic device and/or accompanying service. Alternatively, none of the consumer information may be pre-filled in, and the consumer may be required to fill in some or all of the information requested on the rebate request form personally.

In a traditional paper-based rebate system, a consumer may submit a rebate claim by recording personal information and qualifying UINs on a paper form and mailing the form to the rebate processing center. Although, the rebate claim may be submitted by recording the UINs on the paper form, in some embodiments, the consumer may submit the original receipts or copies of the receipts with the paper form for ease of validation.

In an alternative embodiment, customers may be able to access an electronic rebate request form and submit an electronic rebate claim. For example, customers may be directed to a web page identified by a uniform resource locator (“URL”) accessible using a web browser connected to the internet. The consumer may access the URL in several manners. In one embodiment, the consumer may access the URL using a menu option at the retailer's, manufacturer's, or rebate processing center's website. In some embodiments, the URL may appear to be the retailer's or manufacturer's website, but in fact be the rebate processing center's website that is merely linked to the retailer's or manufacturer's website. Additionally, the consumer may access the URL from any location. In one embodiment, the consumer may access the URL from a home computer system. Alternatively, the consumer may access the URL from a computer located at the retailer's location, such as an in-store kiosk. The electronic rebate request form, accessible via the internet, may contain and/or request similar information as that of the rebate request form described above in that it typically may request transaction information, including the UIN, and selected portions of consumer information, and may include a destination address, rebate promotion information, and instructions for submitting material verifying the qualifying purchase. Alternatively, in some embodiments, an electronic rebate request form may request only enough information to identify the consumer so that the rebate can be provided to the consumer.

The consumer may submit a rebate claim by mail, telephone, internet, or any other suitable means for submitting a rebate claim. In one embodiment, the retailer may provide the consumer with instructions for submitting the rebate claim. In some embodiments, the consumer may not be aware of the involvement of the rebate processing center and may submit the rebate claim to the retailer, e.g., by addressing the rebate claim to the retailer, electronically submitting the rebate claim at the retailer's internet website, etc. The retailer may then forward the rebate claim to the rebate processing center.

To satisfy the rebate offer, as discussed above, consumers may send or submit their used electronic devices and rebate claims 20 to the retail store, distribution center, rebate processing center, or respective agents thereof. In some embodiments, the method may also include providing, to the consumer, a package which may be used to submit the used electronic device. The package may comprise a bag, box, cushion mailer, or other container that is suitable to contain items delivered by mail or courier service. Customers may acquire such packages in various ways. For example, the rebate processing center may send the package to the consumer, via mail or courier service, subsequent to the consumer making a qualifying purchase. Other possibilities include, for example, the consumer acquiring the package at the retail store or distribution center. In some embodiments, the package is provided by the consumers. In one embodiment, the packages may also serve as notification to the consumer. For example, the rebate offer may be affixed to or printed on the package, as previously described.

The used electronic device may be sent in conjunction with the rebate claim, often times both items being submitted in the same package. The used electronic device, however, may be sent at a separate time and in a separate package from that of the of the rebate claim. In some embodiments, the used electronic device and the rebate claim may be sent to separate locations.

In alternative embodiments, the used electronic device may be submitted prior to, or at the time of, purchase of a new electronic device and/or accompanying service. The used electronic device, in such an embodiment, may be submitted directly to the retailer. The retailer may further submit the used electronic device to another entity, including the rebate processing center. In further embodiments, the consumer may receive immediate compensation or discount for the rebate offer at the time of submission of the used electronic device. The retailer, or agent thereof, may subsequently receive compensation for providing the immediate compensation or discount to the consumer.

Upon receipt of the rebate claim and the used electronic device, in some embodiments, the rebate processing center may verify that the rebate request corresponds to a valid qualifying purchase 25. Validating rebate claims may be done in any manner known in the art, and no particular method of validation is particular to the system and method of the embodiments of the present invention. For example, the rebate processing center may employ a computerized software that matches the UINs provided by the consumer on the rebate claim with the UINs provided to the rebate processing center in the point-of-sale data processing and storage system reports. Any combination of consumer identifying information, such as name, address, email address, and the like and purchase identifying information, such as purchase location, purchase date, purchase item, and the like may also be used to verify the rebate claim in lieu of, or in addition to, the UIN. The computerized software may also automatically calculate the rebate total based on the purchase data records. For example, the computerized software, in one embodiment, may automatically determine which items, or combination of items, from a purchase data record are associated with a rebate offer or rebate offers, and determine the total rebate value owed to the consumer. Additionally or alternatively, an operator may be employed to manually verify the rebate claims. Furthermore, the rebate processing center may contact the retail store or distribution center to verify that a qualifying purchase was made. The preceding examples of validation methods are meant only to provide examples of particular embodiments. The various systems and methods of the present invention contemplate any form of validating a rebate claim. Similarly, the rebate processing center may bypass validation, or validation may be performed by another entity in lieu of the rebate processing center.

The rebate processing center may similarly check the rebate claims for fraud, for example, by comparing the name and address of the consumer to known databases containing consumer identities that may be suspicious or have previously been determined to act fraudulently. In other embodiments the fraud-checking step may be performed by an entity other than the rebate processing center or may be omitted entirely.

Hardware and software components used by the rebate processing center may be integral portions of a single computer or server or may be connected parts of a computer network. The hardware and software components may be located within the rebate processing center or may be operated offsite by a third-party subcontractor. In other embodiments, portions of the hardware and software components may be divided among a plurality of locations and connected directly or through a global computer information network, such as the internet.

After the rebate claim has been validated and cleared for issue, the rebate processing center may disburse, to the consumer, the monetary value of the rebate offer satisfied by the consumer 30. For example, the monetary value may be in the form of a check made out to the consumer, a credit to a smart card, a credit to a bank or credit account, a gift certificate for redemption at participating members of a retail network, etc. As used herein, “smart card” refers to a credit or debit card having data storage means on the card, such as a magnetic strip, the storage means capable of storing electronic data that can be read and written by a card reader/writer, allowing the card to store, for example, a running account balance on the card. Additionally, in some embodiments, the monetary value of the rebate claim may be deducted from the cost of the new electronic device, the cost of the accompanying service contract, or both. The preceding examples of disbursement options are meant only to provide examples of particular embodiments. The various methods of the present invention contemplate providing any number and types of additional disbursement options such as a free or discounted warranty on the new electronic device, a donation to a charity on the consumer's behalf, etc.

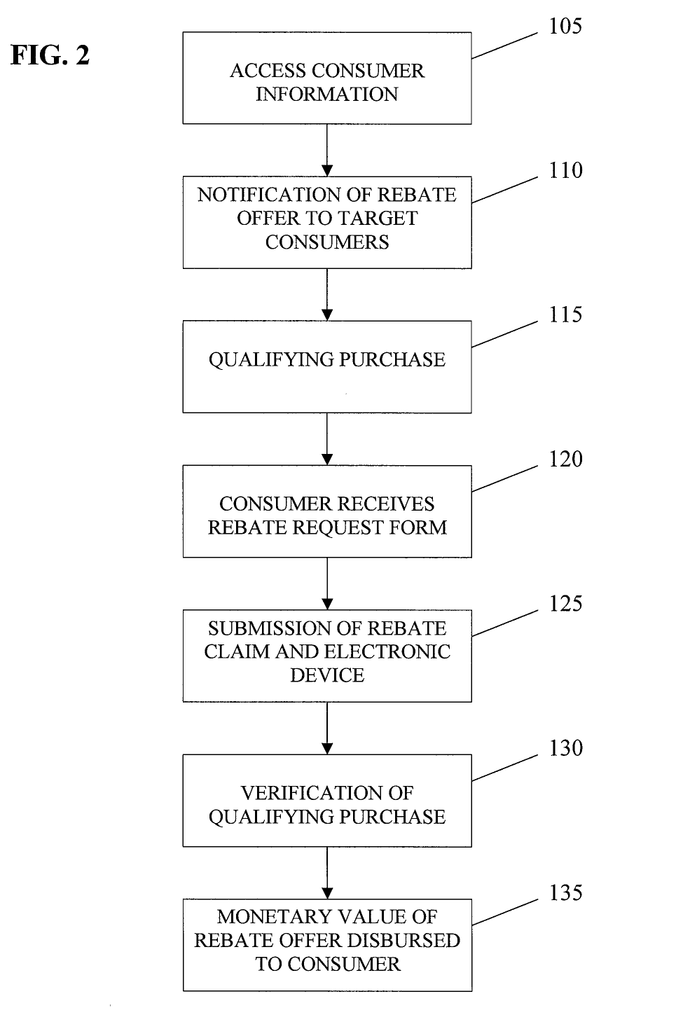

Referring now to FIG. 2, another embodiment of providing a consumer with a rebate in exchange for the recycling of an electronic device is provided. Generally, an alternative embodiment may be used to target particular consumers. For example, particular consumers may be targeted for receiving a rebate offer in order to persuade the consumers to submit and recycle their current electronic device. Some reasons for targeting consumers may include, but are limited to, persuading consumers to upgrade to a newer model of electronic device, persuading consumers to recycle their current model because the current model has a desired refurbished value, etc.

The first step may comprise the rebate processing center accessing information concerning consumers 105 from, for example, retail stores dealing in electronic devices, distribution centers dealing in electronic devices, or companies providing accompanying service contracts. Typically, the consumer information may be provided to the rebate processing center in the form of an electronic database, but may also be provided in printed form. The databases may contain, for example, consumer identifying information, such as names, addresses, email addresses, and the like in addition to information with regard to the purchasing history associated with the consumers. The purchasing history may include any information relating to the purchase of an electronic device and/or accompanying service contract for an electronic device. In one embodiment, the purchasing history may include the type of electronic device as well as the type of accompanying service contract the device is being operated under, including the expiration date of the service contract.

In some embodiments, based upon particular characteristics of the consumer information provided in the database, the retailer, manufacturer, or rebate processing center may select consumers to be notified with regard to a rebate offer 110. Any individual characteristic or combination of characteristics may be used to select consumers. In yet other embodiments, consumers may be selected for any reason, including randomly. Those consumers selected are referred to herein as “target consumers.” Notification 110 in the present embodiment may be achieved in any of the various manners previously described. For example, notifications 110 may be sent to target consumers in the form of an email or delivered mail.

In another embodiment, the retailer, manufacturer, or rebate processing center may select target consumers based on a characteristic of the electronic device that the consumer owns or accompanying service contract that the consumer is currently operating under. For example, the rebate processing center may select target consumers based on one or more of the type, brand, capabilities, and present market value of their associated electronic devices or the accompanying service contract their device is being operated under. Additionally, selection of target consumers may be based on the length of time a consumer has remaining on their existing service contract. The preceding examples of consumer selection characteristics are meant only to provide examples of particular embodiments. The various methods of the present invention contemplate employing any number of additional consumer or device characteristics in making target consumer selections.

Upon consumer notification, the present method may proceed similar to that of the method described previously in that consumers may typically make a qualifying purchase 115, in-person, at a retail store or distribution center, or electronically, via the internet. After making a qualifying purchase consumers may be provided with a rebate request form 120 which may comprise of a request for transaction information, selected portions of consumer information, and may further include a destination address, rebate promotion information, and instructions for submitting material verifying the qualifying purchase. As described previously, the rebate request form may alternatively be provided prior to the qualifying purchase and may further be concomitant with the notification or included as part of the notification. Consumers may subsequently submit a completed rebate request form, i.e., rebate claim, and used electronic device 125 to the rebate processing center, or agents thereof. In alternative embodiments, the used electronic device may be submitted at the time of purchase of a new electronic device and/or accompanying service. Upon receipt of the rebate claim, the qualifying purchase may be verified 130 by the rebate processing center, or agents thereof, and upon verification, the monetary value of the rebate offer may be disbursed to the consumer 135.

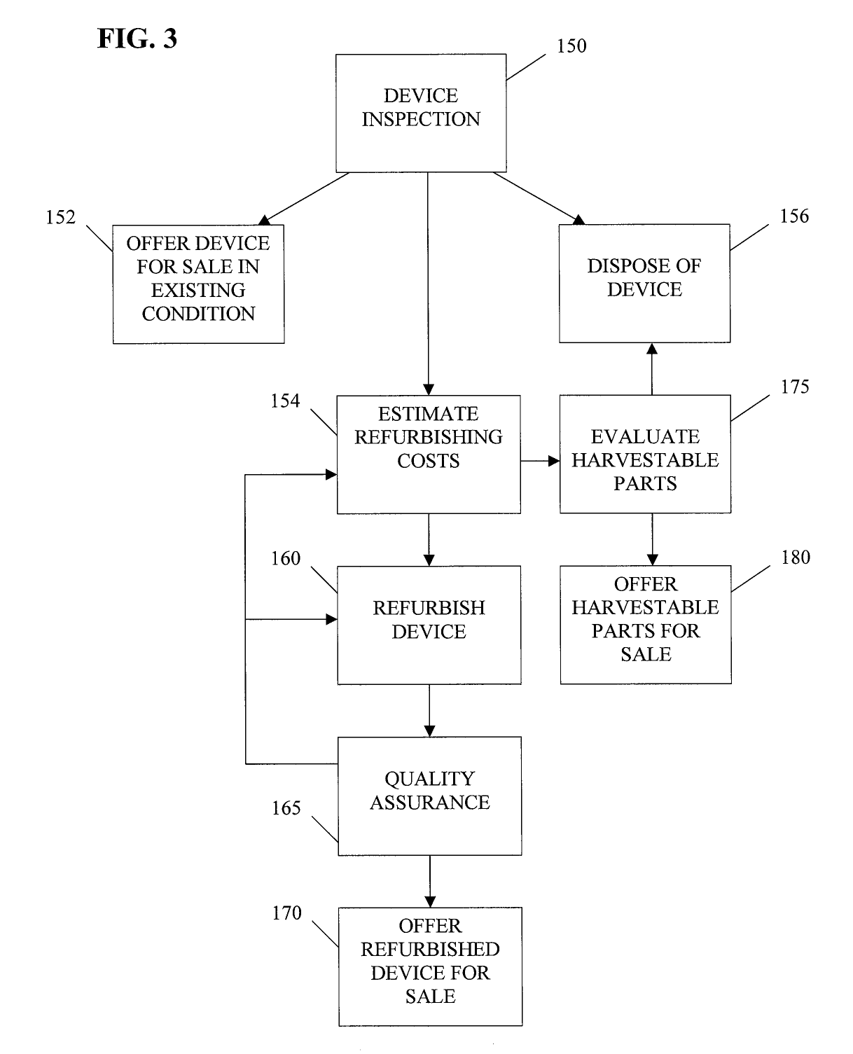

Referring to FIG. 3, a method for recycling used electronic devices is provided. Typically, the method may begin by inspecting the electronic device 150. This may comprise, for example, any or all of visually inspecting the device, testing device functionality, examining for missing parts, etc. Based upon the inspection, in some embodiments, the device may either be offered for sale in its existing condition 152, evaluated for estimated cost of refurbishing 154, or disposed of in accordance with existing environmental policies 156.

In evaluating for estimated cost of refurbishing 154, factors which may be used to estimate refurbishing cost include, but are not limited to, the cost of missing or damaged parts, availability of missing or damaged parts, cost of labor, or the like. In some embodiments, based on the refurbishing cost estimate, the device may either be refurbished 160 or evaluated for harvestable parts 175. Refurbishing 160 may include, but is not limited to, cleaning, replacing missing or damaged parts, repairing damaged parts, or the like. After an electronic device has been refurbished 160, in some embodiments, it may be subjected to a quality assurance analysis 165. Typically, the quality assurance analysis 165 may comprise any test or series of tests which establish that the electronic device is functioning properly. If a device fails the quality assurance analysis 165, in some embodiments, the device may once again be submitted for estimating further refurbishing cost 154 or refurbishing 160. If the device passes the quality assurance analysis 165, in some embodiments, the device may be offered for sale as a refurbished device 170.

If the electronic device is not refurbished, typically, an evaluation of the components of the electronic device 175, or harvestable parts, may be conducted. In some embodiments, based on a characteristic of the harvestable parts, such as market value or type, the harvestable parts and/or components of the electronic device may be harvested and offered for sale 180. If parts and/or components of the electronic device are not harvested, in some embodiments, the device may be disposed of in accordance with existing environmental policies 156. Similarly, if parts and/or components of the electronic device are harvested, that which remains of the device may typically be disposed of in accordance with existing environmental policies 156.

In the embodiments disclosed herein, electronic devices or parts harvested from electronic devices may be sold in any number of ways. For example, the devices may be sold directly from the rebate processing center or distributed to retail stores, distribution centers, and the like for sale. Furthermore, in some embodiments, in lieu of selling for profit, the electronic devices may be donated to a charity or other non-profit organization. The preceding examples of methods of sale are meant only to provide examples of particular embodiments. The various methods of the present invention contemplate employing any number of additional sales methods, such as auctioning, for the sale of electronic devices or parts harvested from electronic devices.

Although various embodiments of the present invention have been described with reference to preferred embodiments, persons skilled in the art will recognize that changes may be made in form and detail without departing from the spirit and scope of the invention. For example, it is recognized that multiple embodiments of rebate validation or other rebate processing may be suitable for use with the various systems and methods of the present invention. Similarly, it is recognized that the rebate claim may be submitted by the consumer in accordance with traditional paper-based rebate systems or “paperless” rebate systems.

We claim:

1. A method of providing a consumer rebate for recycling an electronic device comprising:
receiving a rebate claim from a consumer;
receiving a first electronic device from the consumer; and
transferring the monetary value of the rebate to the consumer;
wherein in exchange for a receiving the rebate claim and first electronic device from the consumer, the consumer is provided, by a third-party, with at least one of a second electronic device and a service associated with the second electronic device.

2. The method of claim 1, wherein the first and second electronic devices are at least one of a cellular phone, mobile email device, pager, two-way radio, mobile communication device, palm computer, pocket computer, radio, television, game system, portable game system, portable music player, computer, camera, and video recorder.

3. The method of claim 2, wherein the first and second electronic devices are the same type of electronic device.

4. The method of claim 2, wherein the first and second electronic devices are different types of electronic devices.

5. The method of claim 3, wherein the first electronic device and the second electronic device are cellular phones and a service associated with the second electronic device is a cellular phone service.

6. The method of claim 5, wherein the cellular phone service is an extension of the duration of the consumer's existing cellular phone service.

7. The method of claim 5, wherein the cellular phone service is a new cellular phone service contract.

8. The method of claim 5 further comprising accessing a database containing client information, wherein the client information comprises client identifying information for at least one current cellular phone service client and cellular phone identifying information for at least one cellular phone associated with the at least one current cellular phone service client.

9. The method of claim 8 further comprising selecting the consumer from the database based on at least one characteristic identified by the cellular phone identifying information associated with the at least one cellular phone associated with the consumer and providing the consumer with a rebate offer.

10. The method of claim 9, wherein the at least one characteristic identified by the cellular phone identifying information identifies the value of the cellular phone.

11. The method of claim 1, wherein receiving a rebate claim from a consumer comprises receiving a rebate claim from the consumer electronically.

12. The method of claim 1, wherein receiving a rebate claim from a consumer comprises receiving a tangible rebate claim from the consumer.

13. A method for providing an incentive to recycle electronic devices comprising:
accessing a database containing at least one consumer having an electronic device and further having consumer information associated with each of the at least one consumer having an electronic device, wherein the consumer information comprises consumer identifying information and electronic device identifying information;
selecting at least one target consumer from the database based on at least one characteristic associated with the electronic device associated with the at least one target consumer selected, wherein the at least one characteristic is determined from the electronic device identifying information; and
providing each of the at least one target consumers with a rebate offer.

14. The method of claim 13, wherein the electronic device identifying information identifies at least one characteristic of the electronic device associated with the value of the electronic device.

15. The method of claim 13, further comprising receiving a rebate claim and a first electronic device from the at least one target consumer.

16. The method of claim 15, further comprising providing the at least one target consumer with a second electronic device and the monetary value of the rebate.

17. The method of claim 15, wherein receiving a rebate claim from a consumer comprises receiving a rebate claim from the consumer electronically.

18. The method of claim 15, wherein receiving a rebate claim from a consumer comprises receiving a tangible rebate claim from the consumer.

19. A system for providing a consumer rebate for recycling an electronic device comprising:
means for receiving submission of a rebate request from a consumer;
means for receiving submission of a first electronic device from the consumer; and
means for validating the rebate request from the consumer;
wherein the rebate is provided to the consumer in relation to the purchase by the consumer of a second electronic device.

20. The system of claim 19, wherein the means for receiving submission of a rebate request allows the consumer to submit the rebate request electronically.

21. The system of claim 19, wherein the means for receiving submission of a first electronic device comprises a package which may be used to submit the used electronic device.

22. The system of claim 21, wherein the package comprises at least one of a bag, box, and cushion mailer.

23. The system of claim 19, wherein the means for validating the rebate request comprises computerized software for automatically validating the at least one rebate request.

24. The system of claim 19, further comprising means for recycling the electronic device.
